(19) United States
(12) Patent Application Publication
(10) Pub. No.: US 2020/0266058 A1
(43) Pub. Date: Aug. 20, 2020

(54) TAILORING HOLES CARRIER CONCENTRATION IN CuXCrYO2

(71) Applicant: LUXEMBOURG INSTITUTE OF SCIENCE AND TECHNOLOGY (LIST), Esch-sur-Alzette (LU)

(72) Inventor: Damien LENOBLE, Wellin (BE)

(21) Appl. No.: 16/651,543

(22) PCT Filed: Sep. 27, 2018
(86) PCT No.: PCT/EP2018/076349

§ 371 Date: Mar. 27, 2020

(30) Foreign Application Priority Data
Sep. 27, 2017 (LU) LU100462

(51) Int. Cl. H01L 21/02; C04B 35/12; H01L 29/24

(52) U.S. Cl. CPC H01L 21/02565; H01L 21/02422; H01L 21/02255; C04B 35/12; C04B 2235/96; C04B 2235/3241; C04B 2235/3281; C04B 2235/6567; H01L 29/24

(57) ABSTRACT

The first object of the invention is directed to a method for modulating the number of charge carriers p in CuₓCr_{y}O₂, the method comprising the steps of (a) depositing a film of CuₓCr_{y}O₂ on a substrate; and (b) annealing at a temperature T the film of deposited CuₓCr_{y}O₂, wherein the subscripts x and y are positive numbers whose the sum is equal or inferior to 2. The method is remarkable in that the log (p)=α T²+β T+γ, wherein the temperature T is expressed degree Celsius, wherein α is a first parameter ranging from −0.00011 to −0.009, wherein β is a second parameter ranging from +0.12 to +0.14, and wherein γ is a third parameter ranging from −27.40 to −22.42. The second object of the invention is directed to a semiconductor comprising CuₓCr_{y}O₂ deposited on a substrate and obtainable by the method in accordance with the first object of the invention.

### CROSS-REFERENCE TO RELATED APPLICATIONS

The present invention is the US national stage under 35 U.S.C. § 371 of International Application No. PCT/EP2018/076349, which was filed on Sep. 27, 2018, and which claims the priority of application LU 100462 filed on Sep. 27, 2017, the content of which (text, drawings and claims) are incorporated here by reference in its entirety.

### FIELD

The invention described hereafter has been generated within the research project entitled “Defect Engineering of P-type Transparent Oxide Semiconductor”, supported by the National Research Fund, Luxembourg (Ref. C12/MS/3959502/DEPTOS).

The invention is directed to the development of a method to finely modulate the electrical conductivity of CuₓCr_{y}O₂, for example of Cu_{0.66}Cr_{1.33}O₂.

### BACKGROUND

In the field of transparent conductive oxides (TCO) copper based delafossites materials (Cu⁺¹M⁺³O⁻², with M a trivalent cation of 3^{rd} group, lanthanides element or a transition metal) started to impose as a promising candidate for the rightful p-type transparent semiconductor, matching the properties of actual standard n-type semiconductors (transmittance greater than 80% in the visible range and electric conductivity up to 1000 S cm⁻¹). The interest on these peculiars compounds ignited after the report of CuAlO₂ as a first p-type semiconductor with proper transparency and a breakthrough reported conductivity of 220 S cm⁻¹ reported for Mg doped CuCrO₂. Various copper based delafossites (M=Cu, Cr, Ga, In, Fe, B) are thoroughly studied in the effort to understand the origin of the p-type conductivity and the transport mechanism within for optimizing subsequently theirs electrical and optical properties. Cu vacancies or oxygen interstitials were mainly suggested as p-type doping source whilst small polaron or band conduction models were proposed in order to explain conduction mechanism in such materials. Moreover, recently reports had shown large conductivity and adequate transparency for highly off-stoichiometric copper chromium delafossites. In these particular compounds the structural phase of delafossite is preserved although a copper deficiency up to 33% is observed.

The synthesis and characterization of highly p-type conductive Cu—Cr—O delafossite thin films has been reported in the studies of Popa P. L., et al. (Applied Materials Today, 2017, 9, 184-191). Conductivities greater than 100 S cm⁻¹ and optical transmittances around 40-50% were measured for non-extrinsically doped films. The determined stoichiometry evidenced a massive deficit of copper, totally compensated by an excess of chromium (Cu_{0.66}Cr_{1.33}O₂). An intrinsic defect, never observed or suggested before, was evidenced using transmission electron microscopy and furthermore suggested as possible source of high carrier concentrations in as-deposited films. It consists in finite lines of copper chained vacancies randomly distributed within crystalline grains. Upon an annealing process at 900° C. these defects are corrected while the electrical conductivity drops almost six orders of magnitude concluding in a carrier concentration drop from 10²¹ to 10¹⁷ cm⁻³ or lower. No chemical changes are observed during the process at the average level whilst the delafossite structure remains unaltered. The experimental results showed the metastable nature of these defects responsible for the conduction in off-stoichiometric copper chromium delafossite.

### SUMMARY

The invention has for technical problem to alleviate at least one of the drawbacks present in the prior art. In particular, the invention has for technical problem to provide a method to finely modulate the electrical conductivity of a known transparent material.

The first object of the invention is directed to a method for modulating the number of charge carriers p in CuₓCr_{y}O₂, the method comprising the steps of (a) depositing a film of CuₓCr_{y}O₂ on a substrate; and (b) annealing at a temperature T the film of deposited CuₓCr_{y}O₂, wherein the subscripts x and y are positive numbers whose the sum is equal or inferior to 2. The method is remarkable in that the log (p)=α T²+β T+γ, wherein the temperature T is expressed degree Celsius, wherein α is a first parameter ranging from −0.00011 to −0.009, wherein β is a second parameter ranging from +0.12 to +0.14, and wherein γ is a third parameter ranging from −27.40 to −22.42.

According to an exemplary embodiment, x is ranging from 0.6 to 0.8.

According to an exemplary embodiment, x is equal to 0.66 and y is equal to 1.33.

According to an exemplary embodiment, a is equal to −0.0001, β is equal to +0.1356 and γ is equal to −24.914.

According to an exemplary embodiment, the step (b) is carried out at a temperature comprised between 600° C. and 1000° C.

According to an exemplary embodiment, the step is carried out during a time comprised between 1 second and 4500 seconds, for example during a time comprised between 20 seconds and 1800 seconds.

According to an exemplary embodiment, the step (a) is a step of patterning on the substrate.

According to an exemplary embodiment, the substrate is glass, sapphire, Si, Si/Si₃N₄, ITO, SiO₂ or any plastic materials, for example glass.

According to an exemplary embodiment, step (b) is carried out in an oven, for example a rapid thermal annealing reactor.

The second object of the present invention is directed to a semiconductor comprising CuₓCr_{y}O₂ deposited on a substrate, obtainable by the method in accordance with the first object of the invention.

The invention is particularly interesting in that the claimed and described method has for the first time shown that a material with a semiconductor behavior can progressively pass from a degenerate to a non-degenerate semiconductor behavior. With the claimed process, it is now possible to obtain a material where its electrical conductivity is finely tuned, because its production depends on the annealing temperature.

It is also highlighted that the material of the present invention has transparency properties.

### DRAWINGS

FIG. 1 exemplarily illustrates a comparison between the XPS spectrum of Cu_{0.66}Cr_{1.33}O₂ as-deposited and as-annealed after 30 seconds and 4000 seconds, in accordance with various embodiments of the invention.

FIG. 2 exemplarily illustrates an elemental composition of the p-oxide type material in function of the etching time, in accordance with various embodiments of the invention.

FIG. 3 exemplarily illustrates a plot of the log (p) in function of the annealing temperature, in accordance with various embodiments of the invention.

FIG. 4 exemplarily illustrates the results of KPFM measurements, in accordance with various embodiments of the invention.

### DESCRIPTION OF AN EMBODIMENT

In the present invention, investigations how controlled thermal treatment can be used as a tool for tailoring electrical and optical properties of as deposited p-type Cu_{0.66}Cr_{1.33}O₂, or of more generally speaking, CuₓCr_{y}O₂ (with the subscripts x and y being positive numbers whose the sum is equal or inferior to 2, for example x ranging from 0.6 to 8 and y ranging from 1.4 to 1.2) have been carried out in order to be used in active transparent devices (as p-n junctions or transistors) next to actual standard n-type materials. In order to achieve this goal the non-equilibrium nature of the defects described above was considered and two different types of thermal treatment are suggested: a fixed amount of time (15 minutes in this case) at various temperatures or different annealing times at a fixed temperature (for example, at 900° C.). The first approach, involving lower temperatures, allows a better control due to the smooth variation of electrical properties. The high temperature “flash” process is more adequate to technological applications where long lasting processes might be considered costly. The temperature range is situated safely lower than 1100° C., the stability limit for copper delafossite phase. The experimental results showed that the controlled thermal treatment can be used as a versatile tool for controlling carrier's concentrations, electrical mobility or even work function, very important parameters for the fabrication of active solid state devices.

Thin films with a thickness around 200 nm were deposited on Al₂O₃ c-cut substrates using a Dynamic Liquid Injection—Metal Organic Chemical Vapour Deposition system DLI-MOCVD, MC200 from Annealsys) whilst bis 2,2,6,6-tetramethyl-3,5-heptanedionate compounds were used as precursors for copper and chromium.

The deposition parameters are: temperature substrate=450° C.; oxygen flow=2000 sccm; nitrogen flow=850 sccm; total process pressure=12 mbar.

The annealing processes were performed in a Rapid Thermal Annealing reactor (Annealsys) at different temperatures and for various time intervals in conditions similar with those during deposition process. Electrical properties were measured using four probes linear configuration. Transmission and reflectance spectra were acquired in the range from 1500 to 250 nm using a Perkin Elmer LAMBDA 950 UV/Vis/NIR Spectrophotometer with a 150 mm InGaAs Integrating Sphere. For X-Ray Photoemission Spectroscopy (XPS) analysis a Kratos Axis Ultra DLD system using a monochromated (Al Kα: hv=1486.7 eV) X-ray was used.source. The Kevin Probe Force Microscopy (KPFM) measurements have been performed on a Bruker Innova using the surface potential mode as amplitude modulation. Surface topography is obtained in the first pass and the surface potential is measured on the second pass. Freshly cleaved highly-oriented pyrolitic graphite (HOPG) is used as reference. The measurements are performed under dry N₂ atmosphere in order to avoid water condensation on the surface.

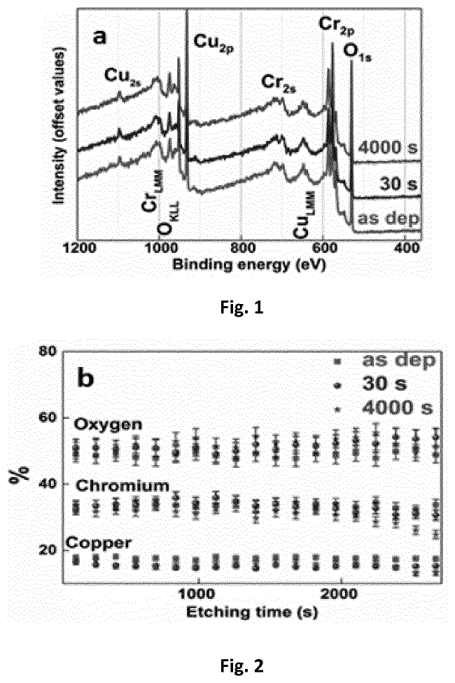

The chemical composition of as-deposited films for various time intervals has been investigated in order to ensure delafossite stability upon thermal treatment. FIG. 1 depicts XPS results for as deposited films and for films annealed for 30 seconds and respectively 4000 seconds. The XPS spectra look similar, suggesting no major changes at chemical level. Besides XPS characteristic peaks for Cu(2p,2s), Cr (2p,2s) and O1s, Auger OKLL Cu and CrLMM peaks are present in the spectra (see FIG. 1). The positions of Cu2p peaks (1/2-932.6 eV and 3/2-952.5 eV) does not change upon annealing. The distance between them is 19.9 eV, a clear indication of delafossite phase. No satellites peaks are observable between and hence one can conclude that only Cu in +1 oxidation state is present. The Cr2p peaks are observed at binding energies of 576.6 (3/2) and 585.6 (1/2) eV respectively. The distance between Cr2p and O1S remains at a constant value 45.3 eV for all samples. Moreover the Auger CuLMM peak observed at a binding energy of 568.6 eV confirms the purity of our delafossite phase.

The chemical compositions for as-deposited and annealed films are shown in FIG. 2. Concentrations around 16,33 and 50% are measured for Cu, Cr and O respectively while no clear tendency of changing O—Cr—Cu ratios is observed during annealing.

Twelve samples, with initials conductivities around 10 S cm⁻¹ were chosen for thermal treatment studies. Half of them were heated for 15 minutes at temperatures of 650, 700, 750, 800 and 850° C. respectively (one kept as reference). For the first sample heated at 650° C., no changes were observed after 15 minutes and consequently the time was furthermore increased up to one hour when a 3 times diminution of electrical conductivity (σ0/σf) was finally observed. This is in agreement with previous work of Götzendörfer (J. of sol-gel Sci. and Tech., 2009, 52, 113-119) where changes in electrical properties of CuCrO₂ were observed starting from temperatures around 620° C.

The second set of samples was heated (one kept again as reference) at 900° C. for 30, 60, 200, 1000 and 4000 seconds, respectively. For the last samples the measured conductivities was beyond the sensitivity of our apparatus (10⁻⁴ S cm⁻¹). For each sample, the conductivity was measured before and after thermal treatment and the results are presented in table 1. Starting from the 700° C. important changes appear upon annealing process. The electrical conductivity decreases monotonous with annealing temperature until a diminution of 50 000 times measured in the case of the sample heated at 850° C.

TABLE 1
Temperature of annealing and carrier's concentration

| t (° C.) | σ₀/σ_{f} | p (cm⁻³⁾ |
|---|---|---|
| no | 1 | 1.68E+21 |
| 650 | 3 | 1.23E+21 |
| 700 | 102 | 6.60E+20 |
| 750 | 5500 | 2.93E+20 |
| 800 | 14000 | 7.32E+19 |
| 850 | 54000 | 9.31E+17 |

Two orders of magnitude in conductivities are lost during short (30-60s) thermal treatments; the decrease continuous with annealing time down to 10-5 S cm-1 range for the sample heated for 4000 seconds.

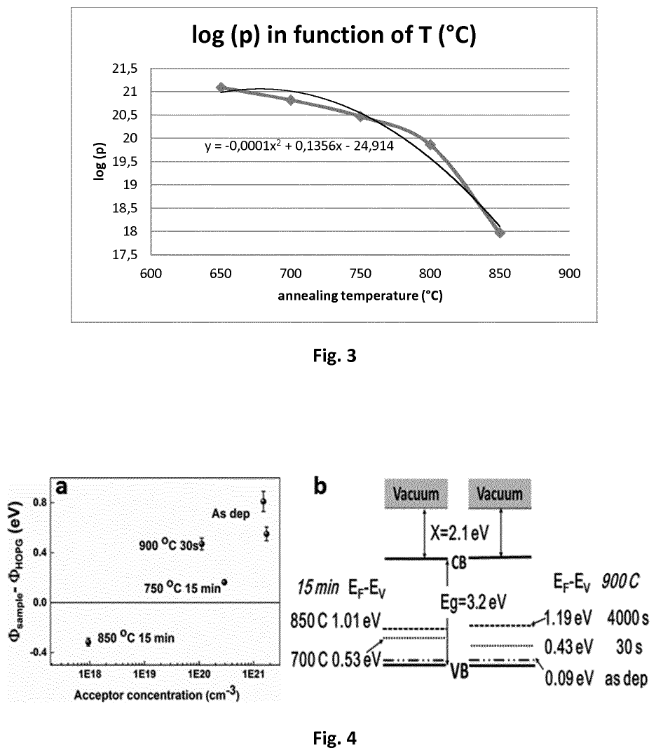

FIG. 3 shows the plot of log (p) in function of the temperature (expressed in ° C.). The 2^{nd} order polynomial has also been plotted, which has allowed to extract the following equation, as well as the following parameters:

log(p)=αT²+βT−γ

α=−0.0001

β=+0.1356

γ=−24.914.

A variance of 10% over those parameter is accepted, so that a, the first parameter, is ranging from −0.00011 to −0.009, β, the second parameter is ranging from +0.12 to +0.14 and γ, the third parameter is ranging from −27.40 to −22.42.

The KPFM (Kelvin Probe Force Measurement) studies were thus performed to obtain information about the composition and the electronic state of the local structures on the surface of the materials. KPFM studies have been carried on six samples, three from each set: both as-deposited reference samples plus two samples from a first set (15 min, 700° C. and 850° C.) and two from a last set (900° C., 30 s and 4000 s).

The measurements were performed in alternate way between HOPG (Highly Oriented Pyrolytic Graphite) and one of the samples. The values are always compared to the latest reference value to avoid possible fluctuations of the tip work function (e.g. due to contaminations). In order to compensate the vacuum levels misalignment KPFM insert the voltage V_{DC}=(ϕₜᵢₚ−ϕₛₐₘₚₗₑ)/e where ϕ_{tip(Pt-Ir)}=5.5 eV. The samples have different doping levels and different Fermi levels were expected. When acceptor concentration Nₐ increases, a decrease of the Fermi is expected and an increase of the work function ϕ should be measured.

Ef−Ev=(X+Eg)−ΔWf

For the copper delafossites, the electronic affinity χ is 2.1 eV while the band gap Eg is 3.2 eV.

The results are shown in FIG. 4, where the work-function difference vs. HOPG (ϕ_{HOPG}=4.4 eV) is shown as a function of the carrier concentration.

It is to be noted that at mid-gap, namely at Eg=1.6 eV, the semiconductor is behaving as an intrinsic semiconductor, namely is not electrically conductive. For as-deposited samples (not annealed samples), the Fermi level is only 0.09 eV (thus far from the conduction band (CB) maximum) and the electrically conduction is therefore relatively high.

When the samples are treated for 30 seconds at a temperature of 900° C., it can be seen on FIG. 4 that the Fermi level has increased to 0.43 eV. For an annealing step of 4000 seconds, the Fermi level has even increased to 1.19 eV, which is almost equivalent to the mid-gap value (1.6 eV). In this case, one has shown that the electrical conductivity can be modulated and that from an electrically conductive material, one can reduce the electrical conductivity and one can modulate it.

For 15 minutes of annealing, at 700° C., the Fermi level has increased to 0.53 eV (from the 0.09 eV of the as-deposited material) while for 15 minutes at 850° C., the Fermi level has increased till 1.01 eV.

An advantage of this method of annealing after deposition is that, as the above, one can modulate the electrical conductivity of the material. Therefore, by doing a local annealing with the help of a laser beam, it has therefore been observed that the electrical conductivity can be modulated at specific place of the material. When the holes disappear, the electrical conductivity decrease, and vice versa. Laser annealing represents a major advantage since only a specific place of the material (actually, where the laser has been in contact with the material) can be modulated.

The local annealing has been carried out with a laser, at a temperature comprised between 600° C. and 1000° C. during a time comprised between 1 second and 1800 seconds. Typically, the local annealing step is ranging from 1 second to 20 seconds.

The power density of the laser beam used in the local annealing step ranges from 1 W/cm² to 10 W/cm². In a typical example, the power density is equivalent to 4 W/cm².

1.-16. (canceled)

17. A method of producing a semiconductor, said method comprising the steps of:
(a) depositing a film of CuₓCr_{y}O₂ on a substrate; and
(b) annealing at a temperature T the film of deposited CuₓCr_{y}O₂;
wherein the subscripts x and y are positive numbers whose the sum is equal or inferior to 2,
the temperature T is obtained from the formula log (p)=a T²+b T+g,
wherein the temperature T is expressed degree Celsius,
wherein p is the desired concentration of charge carriers p in CuₓCr_{y}O₂,
wherein a is a first parameter ranging from −0.00011 to −0.009,
wherein b is a second parameter ranging from +0.12 to +0.14, and
wherein g is a third parameter ranging from −27.40 to −22.42.

18. The method according to claim 17, wherein x is ranging from 0.6 to 0.8.

19. The method according to claim 17, wherein x is equal to 0.66 and y is equal to 1.33.

20. The method according to claim 17, wherein a is equal to −0.0001, b is equal to +0.1356 and g is equal to −24.914.

21. The method according to claim 17, wherein the step (b) is carried out at a temperature comprised between 600° C. and 1000° C.

22. The method according to claim 17, wherein the step is carried out during a time comprised between 1 second and 4500 seconds.

23. The method according to claim 22, wherein the time comprises between 20 seconds and 1800 seconds.

24. The method according to claim 17, wherein the step (a) is a step of patterning on the substrate.

25. The method according to claim 17, wherein the substrate is glass, sapphire, Si, Si/Si₃N₄, ITO, SiO₂ or any plastic materials.

26. The method according to claim 17, wherein step (b) is carried out in an oven.

27. The method according to claim 26, wherein step (b) is carried out in a rapid thermal annealing reactor.

28. The method according to claim 17, wherein step (b) is achieved by a laser beam.

29. The method according to claim 28, wherein step (b) comprises locally scanning the film of CuₓCr_{y}O₂ with the laser beam while modulating the laser power so as to modulate the annealing temperature T and the concentration of charge carriers p.

30. The method according to claim 17, wherein CuₓCr_{y}O₂ is undoped.

31. The method according to claim 17, wherein step (a) is at a temperature of at least 400° C.

32. The method according to claim 17, wherein step (a) the film of CuₓCr_{y}O₂ is crystallized.

33. The method according to claim 17, wherein the y/x ratio is equal to or greater than 1.

34. The method according to claim 33, wherein the y/x ratio is equal to or greater than 2.

35. A semiconductor comprising CuₓCr_{y}O₂ deposited on a substrate, obtainable by a method comprising the steps of:
(a) depositing a film of CuₓCr_{y}O₂ on a substrate; and
(b) annealing at a temperature T the film of deposited CuₓCr_{y}O₂,
wherein the subscripts x and y are positive numbers whose the sum is equal or inferior to 2,
the temperature T is obtained from the formula log (p)=a T²+b T+g,
wherein the temperature T is expressed degree Celsius,
wherein p is the desired concentration of charge carriers p in CuₓCr_{y}O₂,
wherein a is a first parameter ranging from −0.00011 to −0.009,
wherein b is a second parameter ranging from +0.12 to +0.14, and
wherein g is a third parameter ranging from −27.40 to −22.42.
